(19) United States
(12) Patent Application Publication
(10) Pub. No.: US 2020/0176256 A1
(43) Pub. Date: Jun. 4, 2020

(54) METHOD AND SYSTEM FOR IMPROVING WAFER BONDING STRENGTH

(71) Applicant: Wuhan Xinxin Semiconductor Manufacturing Co., Ltd., Wuhan (CN)

(72) Inventors: YIN ZHANG, Wuhan (CN); WANLI GUO, Wuhan (CN)

(21) Appl. No.: 16/355,822

(22) Filed: Mar. 17, 2019

(30) Foreign Application Priority Data
Dec. 3, 2018 (CN) 201811467425.8

(51) Int. Cl. H01L 21/26; H01L 21/67; H01L 21/673

(52) U.S. Cl. CPC H01L 21/26; H01L 21/67316; H01L 21/67115

(57) ABSTRACT

A method for improving wafer bonding strength includes: Step S1: providing a silicon-based bonded wafer; Step S2: placing the bonded wafer in a microwave generating chamber; Step S3: raising the temperature in the microwave generating chamber and maintaining the temperature at a preset threshold by microwave heating; Step S4: after the bonded wafer reaches a predetermined temperature for a predetermined time period, shutting down the microwave power; and Step S5: cooling the bonded wafer. The present invention method can prevent waste of energy in the case of heating a small number of bonded wafers, and avoid a time-consuming preheating process. Therefore, the disclosed method is time-efficient and high-performance.

### BACKGROUND OF THE INVENTION

### 1. Field of the Invention

The present invention relates to the field of semiconductor technology. More particularly, the present invention relates to a method and a system for improving wafer bonding strength.

### 2. Description of the Prior Art

In the integrated circuit processes, three-dimensional (3D) integration has been developed to maintain the existing technology nodes and has become a solution to improve chip performance. By 3D integration of two or more chips with the same or different functions, the performance of the chip can be improved, and the space occupied by the metal interconnection between the functional chips can be greatly reduced, while reducing heat generation, power consumption, and signal delay.

In the 3D integration process, the wafer-to-wafer bonding process is the key. The wafer bonding strength is the key indicator when assessing the quality of the wafer bonding process. At present, it is common to use vertical furnace tube heating to increase the bonding strength between the bonded wafers. However, the heating process of the vertical furnace tube is more stringent, and the heating process requires more energy consumption. Even the vertical furnace tube is not under full load, the energy consumption will not decrease. Moreover, the heating process of the vertical furnace tube is time-consuming, generally up to about 6 hours, which greatly limits the use of the technology.

### SUMMARY OF THE INVENTION

In view of the above problems, the present invention provides a method for improving wafer bonding strength, which includes:

Step S1: providing a silicon-based bonded wafer;

Step S2: placing the bonded wafer in a microwave generating chamber;

Step S3: raising the temperature in the microwave generating chamber and maintaining the temperature at a preset threshold by microwave heating;

Step S4: after the bonded wafer reaches a predetermined temperature for a predetermined time period, shutting down the microwave power; and

Step S5: cooling the bonded wafer.

According to the present invention method, in Step S2, a quartz wafer boat is used to carry the bonded wafer placed in the microwave generating chamber.

According to the present invention method, in Step S2, the bonded wafer is placed in a wafer transfer chamber, and the bonded wafer in the wafer transfer chamber is then loaded into the quartz wafer boat through a first robot arm.

The quartz wafer boat is moved into the microwave generating chamber by a second robot arm.

According to the present invention method, in Step S3, the microwave frequency generated by the microwave generating chamber ranges between 2400 MHz and 2500 MHz.

According to the present invention method, in Step S3, the preset threshold is 200 to 400° C., and/or the predetermined temperature is 200 to 400-C.

According to the present invention method, the predetermined time period is 45 to 60 minutes.

According to the present invention method, in Step S5, the bonded wafer is cooled to room temperature.

The invention further provides a system for enhancing wafer bonding strength, which comprises:

a wafer transfer chamber in which a silicon-based bonded wafer is placed, wherein the wafer transfer chamber includes a quartz wafer boat, and the bonded wafer in the wafer transfer chamber is moved to the quartz wafer boat through a first robot arm to carry the bonded wafer to be heated;

a microwave generating chamber, wherein the quartz wafer boat is moved to the microwave generating chamber through a second robot arm to heat the bonded wafer; and

an air-cooling chamber, wherein the quartz wafer boat is moved to the air-cooling chamber by the second robot arm to cool the bonded wafer placed in the quartz wafer boat.

According to the above-described system, the microwave generating chamber includes a thermocouple for detecting a temperature of the bonded wafer. Alternatively, the temperature of the bonded wafer may be determined by detecting the temperature in the microwave generating chamber.

According to the above-described system, wherein the microwave generating chamber includes a timing module. The timing module sets a predetermined time period to shut down the microwave power of the microwave generating chamber after the bonded wafer reaches the predetermined temperature for the predetermined time period.

Beneficial Effects:

The present invention provides a method and a system for improving wafer bonding strength, which can prevent waste of energy in the case of heating a small number of bonded wafers, and which do not require a time-consuming preheating process. Therefore, the disclosed method and system are time-efficient and high-performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings, which are incorporated herein and form a part of the specification, illustrate embodiments of the present disclosure and, together with the description, further serve to explain the principles of the present disclosure and to enable a person skilled in the pertinent art to make and use the present disclosure.

FIG. 1 is a flow chart showing the steps of a method for improving wafer bonding strength according to an embodiment of the present invention; and

FIG. 2 is a structure diagram showing a wafer bonding enhancement system adopted in the method for improving wafer bonding strength according to an embodiment of the present invention.

Embodiments of the present disclosure will be described with reference to the accompanying drawings.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment.

Further, when a particular feature, structure or characteristic is described in contact with an embodiment, it would be within the knowledge of a person skilled in the pertinent art to affect such feature, structure or characteristic in contact with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures.

The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The invention will now be described in details with reference to the drawings and embodiments.

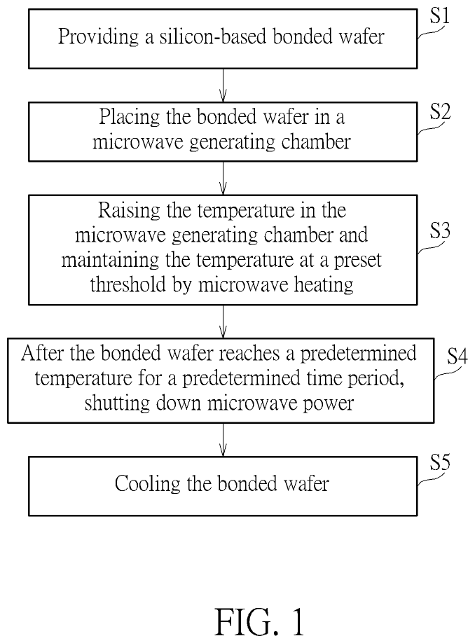

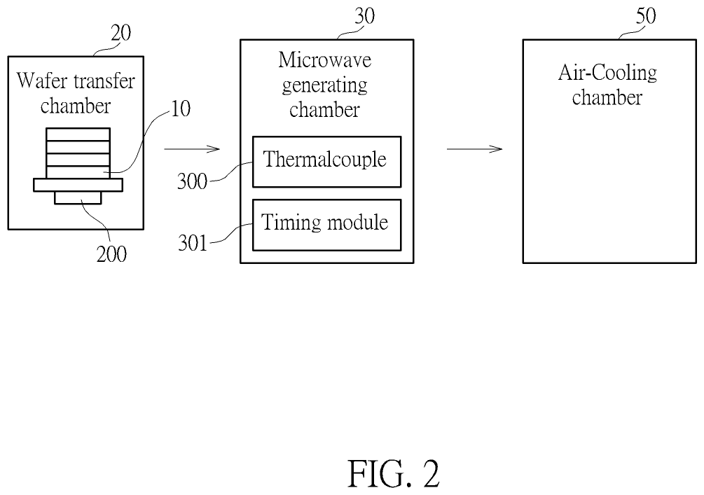

In a preferred embodiment, as shown in FIG. 1, a method for improving wafer bonding strength is proposed. The method may be applied to a wafer bonding enhancement system as shown in FIG. 2. The method for improving the wafer bonding strength may include:

Step S1: providing at least one silicon-based bonded wafer 10, wherein in FIG. 2, four bonded wafers are shown for illustration purposes. On the bonding surface of the bonded wafer 10, there may be uniformly distributed silanol bonds and hydroxyl groups.

Step S2: placing the bonded wafer 10 in a microwave generating chamber 30.

Step S3: radiating each bonded wafer 10 through microwaves generated by the microwave generating chamber 30, such that the silanol bonds (Si—OH) on the bonding surface of each bonded wafer 10 reacts with the hydroxyl group (OH—) to form water and silicon dioxide including silicon-oxygen bonds; wherein the reaction formula is represented as follows: Si-OH+OH-=SiO₂+H₂O. The microwave heating causes the temperature of the microwave generating chamber 30 to rise, and the temperature is maintained at a predetermined threshold.

Step S4: shutting down the microwave power after the bonded wafer reaches a predetermined temperature for a predetermined time period.

Step S5: cooling each bonded wafer 10.

According to the above technical solution, each bonded wafer 10 may be formed by bonding two or more individual wafers, and a corresponding structure may be fabricated in each individual wafer. Since this is a known technique in the art, further description is omitted herein. In Step S3, it should be ensured that the microwave generated by the microwave generating chamber 30 can cover the entire bonding surface of each bonded wafer 10, and the microwave can also cover other portions of the bonded wafer 10. This does not affect the performance or quality of the position of the non-bonded face of the bonded wafer 10.

According to a preferred embodiment, in Step S1, each bonded wafer 10 is subjected to a plasma bombardment and hydrophilic treatment to form uniformly distributed silanol bonds and hydroxyl groups on the bonding surface.

According to the above technical solution, specifically, in Step S1, the plasma bombardment and the hydrophilic treatment may be performed in a sequence. By subjecting the bonded wafer 10 to the plasma bombardment, the silicon-oxygen bonds (Si—O) on the bonding surface of the bonded wafer 10 is broken to form a dangling bond (Si—) of silicon. The bonded wafer 10 is then subjected to the hydrophilic treatment, so that the dangling bond of silicon is bonded to the hydroxyl group (OH—) to form the silanol bond (Si—OH), which is a polar covalent bond. The hydroxyl group that does not transformed into silanol bond may remain in its state, and may be subjected to the reaction with the silanol bond in the subsequent step.

According to a preferred embodiment, in Step S2, the quartz wafer boat 200 may be used to carry the bonded wafers 10 disposed in the microwave generating chamber 30.

According to the above technical solution, the bonded wafers 10 may be orderly arranged or stacked in the quartz crystal boat 200.

In the above embodiment, preferably, in Step S2, the bonded wafers 10 may be placed in a wafer transfer chamber 20, and the bonded wafers 10 in the wafer transfer chamber 20 are moved into the quartz wafer boat 200 by a first robot arm.

According to the above technical solution, the wafer transfer chamber 20 may include the quartz wafer boat 200, and the quartz wafer boat 200 can be moved, for example, by the driving of mechanical means. In Step S5, the cooling can be performed in the independent air-cooling chamber 50. In such case, the transfer of each bonded wafer 10 to the air-cooling chamber 50 can still be completed through the wafer transfer chamber 20.

In the above embodiment, preferably, in Step S2, the quartz wafer boat 200 may be moved into the microwave generating chamber 30 by a second robot arm.

According to a preferred embodiment, the microwave generated by the microwave generating chamber 30 in Step S3 may have a frequency ranging between 2400 MHz and 2500 MHz, for example, 2420 MHz, 2440 MHz, 2450 MHz, 2460 MHz, 2480 MHz, or 2490 MHz, but is not limited thereto.

For example, the bonded wafers 10 are placed in a microwave electromagnetic field of 2450 MHz high frequency, and the electric energy is converted into microwave through the magnetic control head. The polar covalent bonds inside the silicon wafer generate a large amount of heat along with the high frequency vibration and intermolecular friction, and the electromagnetic energy of the microwave is converted into heat energy.

According to a preferred embodiment, in Step S3, the preset threshold is 200 to 400° C., and/or the predetermined temperature is 200 to 400° C. For example, the preset threshold and/or the predetermined temperature may be 220° C., 250° C., 280° C., 320° C., 360° C., 380° C., but is not limited thereto.

According to the above technical solution, the microwave generating chamber 30 may include a thermocouple 300, which may be used to detect the temperature of the bonded wafer 10, or indirectly measure the bonded wafer 10 by detecting the temperature in the microwave generating chamber 30.

According to a preferred embodiment, the preset time is 45 to 60 minutes, for example, 47 minutes, 49 minutes, 51 minutes, 53 minutes, 55 minutes, 57 minutes, or 59 minutes, but is not limited thereto.

Conventionally, the wafer is heated through a form of heat conduction, which easily forms a temperature gradient difference from the surface to the inside of the wafer. In stark contrast, the proposed microwave heating approach has a corresponding medium selectivity, that is, penetrability, so that basically the internal and external parts of the wafer are simultaneously heated, and the conversion and transfer effects are more rapid. Moreover, the external metal housing of the microwave heating system can only reflect microwaves and barely adsorb microwaves, so that recombination of the Si—OH bonds (Si-OH+OH-=SiO₂+H₂O) at the bonding interface of the bonded wafer is promoted.

According to a preferred embodiment, in Step 5, the bonded wafers 10 may be cooled by nitrogen or compressed dry air and the bonded wafers 10 may be cooled to room temperature.

According to the above technical solution, other inert gases may also be selected to complete the cooling.

According to a preferred embodiment, the above-described method for improving wafer bonding strength is implemented with the wafer bonding enhancement system, as shown in FIG. 2, including:

a wafer transfer chamber 20 in which at least one silicon-based bonded wafer 10 is placed, wherein the wafer transfer chamber 20 includes a quartz wafer boat 200, and the bonded wafer 10 in the wafer transfer chamber 20 is moved to the quartz wafer boat 200 through a first robot arm to carry the bonded wafer 10 to be heated;

a microwave generating chamber 30, wherein the quartz wafer boat 200 is moved to the microwave generating chamber 30 through a second robot arm to heat the bonded wafer 10; and

an air-cooling chamber 50, wherein the quartz wafer boat 200 is moved to the air-cooling chamber 50 by the second robot arm to cool the bonded wafer 10 placed in the quartz wafer boat 200.

According to the above technical solution, the microwave generating chamber 30 includes a thermocouple 300 for detecting the temperature of the bonded wafer 10; or by detecting the temperature in the microwave generating chamber 30 to measure the temperature of the bonded wafer 10. Specifically, the temperature of the microwave generating chamber 30 is raised by microwave heating, which is detected by the thermocouple 300 and maintained a preset threshold, wherein the preset threshold is 200-400° C., and/or the predetermined temperature is 200-400° C. For example, the preset threshold and/or the predetermined temperature may be 220° C., 250° C., 280° C., 320° C., 360° C., 380° C., but is not limited thereto.

According to the above technical solution, the microwave generating chamber 30 includes a timing module 301. The timing module 301 sets a preset time to shut down the microwave power of the microwave generating chamber 30 when the bonded wafer reaches the predetermined temperature and remains at the predetermined temperature for the predetermined time period. The predetermined time period is 45 to 60 minutes, for example, 47 minutes, 49 minutes, 51 minutes, 53 minutes, 55 minutes, 57 minutes, or 59 minutes, but is not limited thereto.

Since the wafer bonding strength is determined by the rich ratio of Si—O bonds per unit area formed after the plasma bombardment on the surface of the silicon wafer. Therefore, microwave heating for a certain time period does not affect the final wafer bonding strength.

The inertia of microwave heating is small, which can realize rapid control of temperature rise and fall, and is suitable for continuous multi-condition automatic control. Therefore, the corresponding process time can be saved.

In summary, the present invention provides amethodanda system for improving wafer bonding strength, which can prevent waste of energy in the case of heating a small number of bonded wafers, and which do not require a vertical furnace having time-consuming preheating process. By uniformly heating the bonding surface of the bonded wafer through the microwave, the whole process is fast and efficient.

Exemplary embodiments of the specific structure of the specific embodiments are given by way of illustration and the accompanying drawings, and other transitions are possible in accordance with the spirit of the invention. Although the above invention proposes a prior preferred embodiment, these are not intended to be limiting.

For those skilled in the art, after reading the above description, various changes and modifications undoubtedly will be obvious. Accordingly, the appended claims are to cover all such modifications and modifications. The scope and content of any and all equivalents of the claims are intended to be within the scope and spirit of the invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for improving wafer bonding strength, comprising:
Step S1: providing a silicon-based bonded wafer;
Step S2: placing the bonded wafer in a microwave generating chamber;
Step S3: raising the temperature in the microwave generating chamber and maintaining the temperature at a preset threshold by microwave heating;
Step S4: after the bonded wafer reaches a predetermined temperature for a predetermined time period, shutting down microwave power; and
Step S5: cooling the bonded wafer.

2. The method according to claim 1, wherein in Step S2, a quartz wafer boat is used to carry the bonded wafer placed in the microwave generating chamber.

3. The method according to claim 2, wherein in Step S2, the bonded wafer is placed in a wafer transfer chamber, and the bonded wafer in the wafer transfer chamber is loaded into the quartz wafer boat through a first robot arm.

4. The method according to claim 1, wherein in Step S3, the microwave frequency generated by the microwave generating chamber ranges between 2400 MHz and 2500 MHz.

5. The method according to claim 1, wherein in Step S3, the preset threshold is 200 to 400° C., and/or the predetermined temperature is 200 to 400° C.

6. The method according to claim 1, wherein the predetermined time period is 45 to 60 minutes.

7. The method according to claim 1, wherein in Step S5, the bonded wafer is cooled to room temperature.

8. A system for enhancing wafer bonding strength, comprising:
a wafer transfer chamber in which a silicon-based bonded wafer is placed, wherein the wafer transfer chamber includes a quartz wafer boat, and the bonded wafer in the wafer transfer chamber is moved to the quartz wafer boat through a first robot arm to carry the bonded wafer to be heated;
a microwave generating chamber, wherein the quartz wafer boat is moved to the microwave generating chamber through a second robot arm to heat the bonded wafer; and
an air-cooling chamber, wherein the quartz wafer boat is moved to the air-cooling chamber by the second robot arm to cool the bonded wafer placed in the quartz wafer boat.

9. The system according to claim 8, wherein the microwave generating chamber includes a thermocouple for detecting a temperature of the bonded wafer; alternatively, the temperature of the bonded wafer is determined by detecting the temperature in the microwave generating chamber.

10. The system according to claim 8, wherein the microwave generating chamber includes a timing module, wherein the timing module sets a predetermined time period to shut down microwave power of the microwave generating chamber after the bonded wafer reaches a predetermined temperature for the predetermined time period.
